(19) United States
(12) Patent Application Publication
(10) Pub. No.: US 2025/0063686 A1
(43) Pub. Date: Feb. 20, 2025

(54) IMMERSION-TYPE LIQUID-COOLING DEVICE AND IMMERSION-TYPE LIQUID-COOLING SYSTEM

(71) Applicant: Beijing Bytedance Network Technology Co., Ltd., Beijing (CN)

(72) Inventors: Jian WANG, Beijing (CN); Bin LIN, Beijing (CN); Zhichao LV, Beijing (CN); Shifeng WANG, Beijing (CN); Ruidong WANG, Beijing (CN)

(21) Appl. No.: 18/723,057

(22) PCT Filed: Dec. 12, 2022
(86) PCT No.: PCT/CN2022/138497

§ 371 Date: Jun. 21, 2024

(30) Foreign Application Priority Data
Dec. 22, 2021 (CN) 202111580493.7

(51) Int. Cl. H05K 7/20

(52) U.S. Cl. CPC H05K 7/20236; H05K 7/20263; H05K 7/20272; H05K 7/20763

(57) ABSTRACT

Provided in embodiments of the disclosure are an immersion-type liquid-cooling device and an immersion-type liquid-cooling system. The immersion-type liquid-cooling device comprises: a cooling tank adapted to accommodate a main cooling liquid in a sealed manner; a main heat dissipation apparatus attached to the cooling tank and comprising an inner cavity enclosed by a housing, and a main circulating component and heat exchanger accommodated in the inner cavity, wherein the inner cavity is in communication with the cooling tank in a sealed manner, and the main circulating component is adapted to circulate the main cooling liquid between the cooling tank and the exterior of the heat exchanger; and a cold source interface coupled to the main heat dissipation apparatus and configured to allow an auxiliary cooling liquid to circulate between an external cold source and the interior of the heat exchanger.

### CROSS-REFERENCE TO RELATED APPLICATION(S)

This application is a Continuation Application of International Patent Application No. PCT/CN2022/138497, filed on Dec. 12, 2022, which claims priority to Chinese Application No. 202111580493.7 filed on Dec. 22, 2021 and titled “IMMERSION-TYPE LIQUID-COOLING DEVICE AND IMMERSION-TYPE LIQUID-COOLING SYSTEM”, the disclosure of which is incorporated herein by reference in its entity.

### FIELD

Embodiments of the present disclosure relate generally to a field of data centers and, more particularly, to an immersion-type liquid-cooling device and immersion-type liquid-cooling systems for providing cooling for the data center.

### BACKGROUND

With the rapid development of Internet, artificial intelligence, cloud computing and high-performance computing, the data center not only promotes great changes in corporate business, but also greatly improves the quality of life. Currently, the data center has been formally incorporated into a new infrastructure. As a result, the data center expands from serving some enterprises to serving the whole society and becomes a new kind of infrastructure.

The new infrastructure puts higher demands on heat dissipation solutions and overall energy efficiency of the data center. On the one hand, With the advent of a big data era, data is growing at a speed beyond the imagination, the processing, storage and transmission of massive data require the power consumption of an IT device to be multiplied, and chip heat dissipation becomes a great challenge. Traditional data center cooling solutions have been difficult to meet the needs of efficient heat dissipation of an electronic information device. At the same time, the country, local governments, and industries have issued energy policies successively, and put forward higher requirements for energy-saving indicators of the data center. A more energy-saving, intensive and efficient IT device and a data center overall solution is desirable strongly, and advantages of an immersion-type liquid-cooling solution in terms of energy efficiency and rapid delivery are valued.

### SUMMARY

Embodiments of the present disclosure provide an immersion-type liquid-cooling device and immersion-type liquid-cooling systems to at least partially address the above-identified problem(s) and other potential problems in the prior art.

In one aspect of the present disclosure, an immersion-type liquid-cooling device is provided. The immersion-type liquid-cooling device comprises: a cooling tank adapted to accommodate a main cooling liquid in a sealed manner, so as to immerse, in the main cooling liquid, an electronic device to be cooled: a main heat dissipation apparatus attached to the cooling tank and comprising an inner cavity enclosed by a housing and a main circulating component and a heat exchanger accommodated in the inner cavity, wherein the inner cavity is in communication with the cooling tank in a sealed manner, and the main circulating component is adapted to circulate the main cooling liquid between the cooling tank and an exterior of the heat exchanger; and a cold source interface coupled to the main heat dissipation apparatus and configured to allow an auxiliary cooling liquid to circulate between an external cold source and an interior of the heat exchanger such that the auxiliary cooling liquid exchanges heat with the main cooling liquid at the heat exchanger.

With the deployment of the immersion-type liquid-cooling device according to an embodiment of the present disclosure, on the one hand, since the main heat dissipation apparatus itself has an internal circulation capacity (main cooling liquid circulation) and an external circulation interface (allowing auxiliary cooling liquid circulation), the main heat dissipation apparatus itself forms a modular apparatus without the need for an additional cold distribution unit. In this way, a liquid cooling device according to an embodiment of the present disclosure can provide main heat dissipation apparatuses with a plurality of standards for different electronic devices and the like and thereby improve cooling efficiency. On the other hand, a modular liquid cooling device is formed by attaching together the main heat dissipation apparatus having the internal circulation capacity and the external circulation interface and the cooling tank. When a liquid cooling device according to an embodiment of the present disclosure is deployed, the deployment can be completed by only coupling a reserved interface of a data center and the cold source interface of the liquid cooling device. thereby forming a distributed liquid cooling system. In this way, the deployment of the liquid cooling device is significantly simplified. In addition, a user can select a different number of liquid cooling devices according to the scale required. Only a certain number of reserved interfaces need to be reserved, and the user can increase or decrease the required liquid cooling devices at any time according to the adjustment of business volume, thereby making the deployment of liquid cooling devices for the data center more flexible and significantly improving the deployment efficiency.

In some embodiments, the main heat dissipation apparatus is detachably attached to the cooling tank. For example, in some embodiments, the main heat dissipation apparatus may be indirectly attached to the cooling tank through a holder. In this manner, main heat dissipation apparatuses with different standards can be selected for different electronic devices to improve cooling efficiency, thereby facilitating carbon neutralization.

In some embodiments, the immersion-type liquid-cooling device further comprises a holder adapted to carry the cooling tank and the main heat dissipation apparatus. By adopting the holder carrying the cooling tank and the main heat dissipation apparatus, the liquid cooling device is made easier to be deployed.

In some embodiments, the plurality of electronic devices is arranged in the cooling tank along an extension direction, and a size of the immersion-type liquid-cooling device in the extension direction is not greater than 1.5 times a size of a height of the immersion-type liquid-cooling device. In comparison with a conventional liquid cooling device in which the length of the cooling tank itself is 2-3 times or more the height thereof, the size in the extension direction of the immersion-type liquid-cooling device including the main heat dissipation apparatus according to the present disclosure is not greater than 1.5 times, for example, 1 time or less the height thereof. In this way, a miniaturized liquid cooling device is achieved. Miniaturization provides advantages, such as facilitating flexible adjustments to the scale of cooling required, thereby improving the utilization of the liquid cooling system and the liquid cooling medium therein. On the other hand, miniaturization leads to more precise control of the cooling liquid, thereby improving precise cooling control of the electronic device while saving the cooling medium.

In some embodiments, the size of the immersion-type liquid-cooling device in the extension direction is less than the size of the height of the immersion-type liquid-cooling device.

In some embodiments, the size of the immersion-type liquid-cooling device in the extension direction is less than a size of one half of the height of the immersion-type liquid-cooling device. In this way, miniaturization of the liquid cooling device is further achieved, thereby further improving precise cooling control of the electronic device while saving the cooling medium.

In some embodiments, the immersion-type liquid-cooling device further comprises a plurality of inlet and outlet through holes arranged between the cooling tank and the inner cavity of the main heat dissipation apparatus in a sealed manner for circulating the main cooling liquid between the cooling tank and the exterior of the heat exchanger. By providing a redundant arrangement of inlet and outlet through holes, the reliability of the liquid cooling device is improved.

In some embodiments, the cooling tank is set with a plurality of standards, and cooling tanks with the plurality of standards differ in depth and/or in size in the extension direction, and the holder is adapted to accommodate a cooling tank with at least one of the plurality of standards. In this way, the user can reasonably select a cooling tank with the required standard according to the size of the electronic device to be cooled, thereby further saving the main cooling liquid and allowing for precise control of the main cooling liquid.

In some embodiments, the immersion-type liquid-cooling device further comprises a lifting bracket coupled to the holder and adapted to support at least one of the cooling tank and the main heat dissipation apparatus. The lifting bracket can elevate the cooling tank with a lower depth, thereby improving the stability of the structure and the reliability of the liquid cooling device. In addition, this arrangement also improves the ease of coupling the cold source interface with the reserved interface of the liquid cooling system.

In some embodiments, the main heat dissipation apparatus is set with a plurality of standards, and main heat dissipation apparatuses with the plurality of standards have different circulating heat dissipation capacities, and the holder is adapted to accommodate the main heat dissipation apparatus with at least one of the plurality of standards. In this way, the user can select a main heat dissipation apparatus with the desired standard based on the number of cooling tanks with different standards and/or electronic devices, thereby improving the circulating and cooling efficiency of the main heat dissipation apparatus.

In some embodiments, the immersion-type liquid-cooling device further comprises a lid coupled to the cooling tank to seal a top opening of the cooling tank. In this way, maintenance of the main cooling liquid in the cooling tank and the electronic device is more facilitated, thereby improving maintenance efficiency.

In some embodiments, the lid is coupled to the cooling tank by a hinge in a rotatable manner. In this way, the convenience of maintenance of the liquid cooling device is further improved, thereby further improving the maintenance efficiency.

In some embodiments, the main heat dissipation apparatus further comprises a liquid occupied block arranged in the inner cavity. The liquid occupied block can effectively decrease the amount of main cooling liquid, thereby reducing the cost of liquid cooling device.

In some embodiments, the cold source interface includes at least two sets of cold source interfaces. In this way, the cold source interface also forms a redundant arrangement, thereby further improving the reliability of the liquid cooling device.

In some embodiments, the cold source interface is at least partially arranged on the housing. In this way, the liquid cooling device is easier to be deployed.

In a second aspect of the present disclosure, an immersion-type liquid-cooling system is provided. The immersion-type liquid-cooling system comprises at least one immersion-type liquid-cooling device of the first aspect described hereinbefore; and an auxiliary cooling apparatus coupled to the cold source interface of the at least one immersion-type liquid-cooling device and adapted to circulate an auxiliary cooling liquid between an external cold source and the interior of the heat exchanger.

In some embodiments, the at least one immersion-type liquid-cooling device comprises a plurality of immersion-type liquid-cooling devices, and the immersion-type liquid-cooling system further comprises a plurality of reserved interfaces adapted to be coupled to the cold source interface.

In some embodiments, the immersion-type liquid-cooling system further comprises a base comprising a plurality of accommodating portions provided at predetermined positions for providing the plurality of immersion-type liquid-cooling devices, the plurality of accommodating portions corresponding to the plurality of reserved interfaces. In a case of a large-scale deployment of servers, the deployment time of data center can be further reduced by providing the base.

In some embodiments, the main cooling liquid comprises a fluorinated liquid or a mineral oil; and/or the auxiliary cooling liquid comprises deionized water.

In a third aspect of the present disclosure, an immersion-type liquid-cooling system for a large-scale cluster deployment is provided. The immersion-type liquid-cooling system comprises a base comprising a plurality of accommodating portions provided at predetermined positions: a plurality of reserved interfaces corresponding to positions of the plurality of accommodating portions: an auxiliary cooling apparatus configured between the plurality of reserved interfaces and an external cold source; and a plurality of immersion-type liquid-cooling devices according to the first aspect described hereinbefore, which are arranged in the accommodating portions, and cold source interfaces of the immersion-type liquid-cooling devices are coupled to the plurality of reserved interfaces. When the immersion-type liquid-cooling devices are deployed in a large-scale cluster, the immersion-type liquid-cooling system with the large-scale cluster deployment can be formed by providing a base and reserved interfaces in the data center in advance, arranging the liquid-cooling devices in a data center machine room in advance, and connecting a water supplying and returning pipeline at the side of the external cold source and completing the debugging, without providing the electronic device and the main cooling liquid. When there is a business need, an electronic device then is procured and deployed into the system, and finally the main cooling liquid is filled into the liquid cooling device where the electronic device is placed. To this end, the deployment of the entire data center is completed, and in this way, the deployment time of data center can be greatly reduced.

It should be understood that this section is not intended to identify key or critical features of embodiments of the present disclosure, nor is it intended to be used to limit the scope of the disclosure. Other features of the present disclosure will become readily apparent from the following description.

### BRIEF DESCRIPTION OF THE DRAWINGS

The above and other objects, features and advantages of the present disclosure will become more apparent by describing in detail exemplary embodiments thereof with reference to the accompanying drawings in which like reference numerals generally refer to the same parts throughout the exemplary embodiments of the disclosure.

FIG. 1 shows a schematic view of a cooling tank used in a conventional immersion-type liquid-cooling system;

FIG. 2 shows a schematic perspective view of an immersion-type liquid-cooling device according to an embodiment of the present disclosure:

FIG. 3 shows a schematic perspective view of the immersion-type liquid-cooling device according to the embodiment of the present disclosure viewed from another angle:

FIG. 4 shows a schematic perspective view of the immersion-type liquid-cooling device according to the embodiment of the present disclosure viewed from another angle, in which a lid is opened to facilitate displaying the electronic device therein;

FIG. 5 shows a schematic side view of an immersion-type liquid-cooling device according to an embodiment of the present disclosure:

FIGS. 6 to 8 show schematic views of various types of electronic devices arranged in an immersion-type liquid-cooling device according to an embodiment of the present disclosure:

FIG. 9 shows a schematic view of a main heat dissipation apparatus of an immersion-type liquid-cooling device being extracted from a holder according to an embodiment of the present disclosure:

FIG. 10 shows a schematic view of circulation of a main cooling liquid inside an immersion-type liquid-cooling device according to an embodiment of the present disclosure:

FIG. 11 shows a schematic side view of a main heat dissipation apparatus according to an embodiment of the present disclosure:

FIG. 12 shows a schematic deployment view of an immersion-type liquid-cooling system according to an embodiment of the present disclosure; and

FIG. 13 shows a schematic view of an array of immersion-type liquid-cooling devices in an immersion-type liquid-cooling system according to an embodiment of the present disclosure.

### DETAILED DESCRIPTION OF EMBODIMENTS

The principles of the present disclosure will now be described with reference to various exemplary embodiments shown in the drawings. It should be understood that the description of these embodiments is merely intended to enable those skilled in the art to better understand and to further practice the present disclosure, and is not intended to limit the scope of the present disclosure in any way. It should be noted that similar or identical reference numbers may be used throughout the drawings where feasible and may indicate similar or identical functionality. One skilled in the art will readily recognize from the following description that alternative embodiments of the structures and methods illustrated herein may be employed without departing from the principles of the disclosure described herein.

With the rapid development of the information and communication industry, the integration level and thermal density of electronic devices are increasing. Faced with the increasing power consumption of chips and the increasing integration level of electronic devices, the traditional technology of using air as a medium to dissipate heat for electronic products is increasingly unable to meet the demand, the industry began to seek higher-density heat dissipation solutions, immersion-type cooling began to come into view:

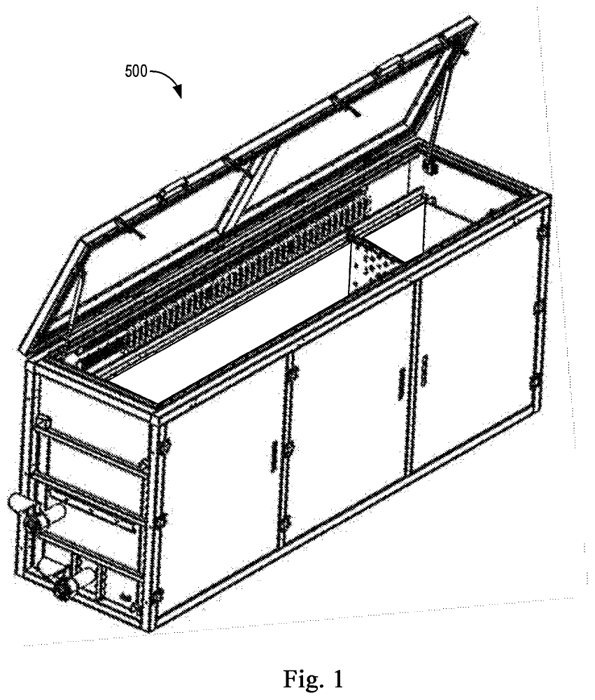

Immersion-type cooling. also known as immersion-type liquid-cooling, is to immerse an electronic device 200, such as a server, in a non-conductive liquid to dissipate heat, thereby controlling its temperature within a reasonable range. In the following, the concepts of the present disclosure will be described mainly with reference to examples in which electronic devices are taken as various types of servers used in the data center. It should be understood that the liquid cooling device 100 or liquid cooling system according to embodiments of the present disclosure is also suitable to any other suitable occasions where an electronic device is required to be cooled. A cooling tank 500 typically used in conventional immersion-type cooling schemes is shown in FIG. 1. In a data center, an electronic device employing immersion-type cooling is immersed in a cooling liquid in the cooling tank 500, and the cooling liquid exchanges heat with air or an auxiliary cooling liquid such as water at a heat exchanger, thereby achieving efficient cooling.

At the beginning of the rise of immersion-type liquid cooling, in order to meet the demands of larger-scale data centers, a cooling tank 500 having a larger volume is generally used to accommodate more electronic devices in one cooling tank 500. A plurality of electronic devices such as servers are arranged in the cooling tank 500 along an extension direction. The size (i.e. length) of the conventional cooling tank 500 in the extension direction can generally reach more than 50 U, and the physical length is about 2-3 meters or even longer. The U is a unit indicating an external size of an electronic device, and is an abbreviation for unit. With the rapid development of the information and communication industry, many problems have been encountered with the larger cooling tank 500. For example, due to the large volume, the deployment flexibility is low; thereby increasing the complexity and cost in operational maintenance. In addition, since the length of the cooling tank is long, a user generally can operate and maintain the electronic devices immersed therein only in a width direction of the cooling tank 500 while maintaining the electronic devices, which causes inconvenience to the maintenance of the electronic devices.

In addition, the cooling liquid of the cooling tank 500 currently has a high cost. Since the cooling tank 500 has a large volume, a large amount of cooling liquid is required, which will inevitably increase the cost, especially in a case that such many electronic devices are not required in the cooling tank 500. For example, assuming that an accommodating capacity of the cooling tank 500 is 50 electronic devices, but for some small businesses, for example, only 10 electronic devices may be required. This also requires the same cooling tank and supplies the same or even more cooling liquid when using such the cooling tank 500 as in the cases where 10 electronic devices are provided and where 50 electronic devices are provided, which results in a significant cost increase.

Further, since the current immersion-type liquid-cooling system has poor stability and the inlet and outlet interface for the cooling liquid is prone to problems such as blockage, the electronic device(s) immersed in the entire cooling tank 500 is easily caused to be unable to work, thereby resulting in a large loss.

As mentioned in the foregoing, the immersion-type liquid-cooling system can cool many types and sizes of electronic devices. However, the current cooling tank 500 generally has a uniform greater depth in order to accommodate the electronic device with the largest size. In this case, when the electronic device with a relatively small size is immersed therein, a large portion of the space therein is left empty, thereby also causing a waste of the space and the cooling liquid therein.

Further, the conventional cooling tank 500 cannot currently implement heat exchange between the cooling liquid and an auxiliary cooling liquid such as water in a heat exchanger alone. Currently, for the conventional cooling tank 500, it is necessary to provide a special cold distribution unit (CDU) for heat exchange. However, the deployment of the cold distribution unit, the deployment of the cooling tank 500 and the deployment of the electronic device(s) provided therein all need to be in a certain matching and proportional relationship, thereby resulting in the complexity of the design of the conventional immersion-type liquid-cooling system, and resulting in the low efficiency of design and construction, etc. In addition, due to the matching and proportional relationship among the cold distribution unit, the cooling tank and the electronic device(s), it is difficult for the liquid cooling system to adjust the number of electronic devices and the like according to the adjustment of the business volume after the liquid cooling system is deployed, resulting in various problems such as poor flexibility.

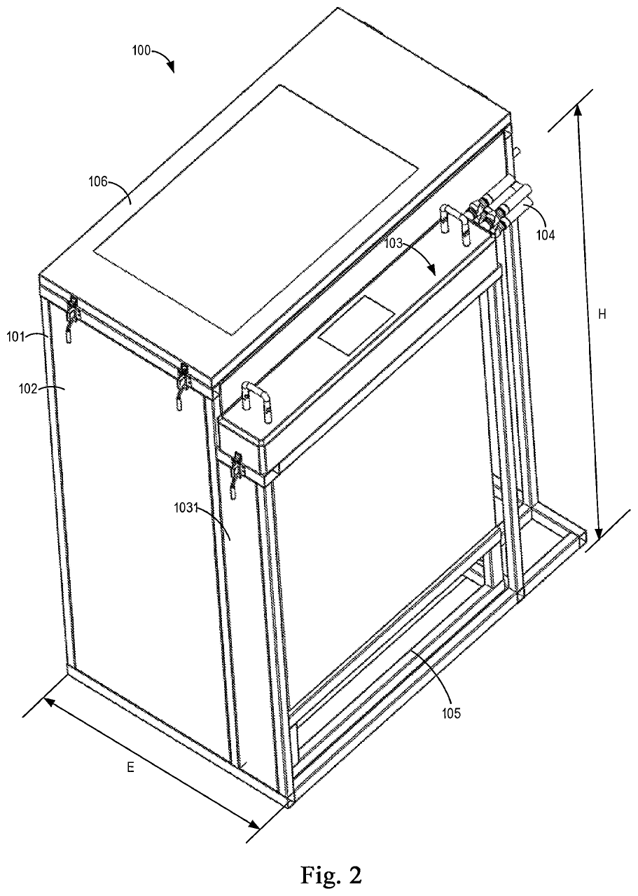

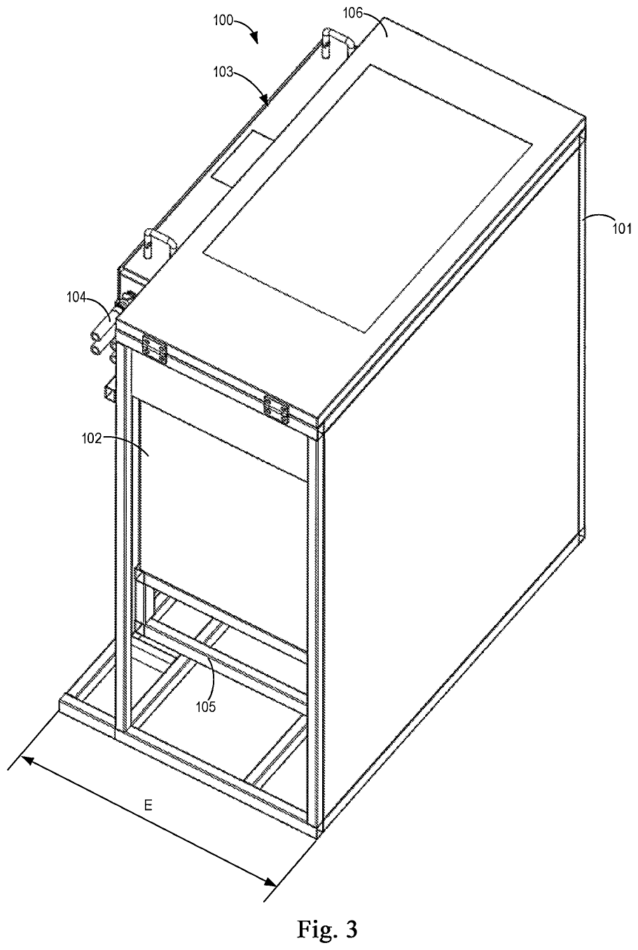

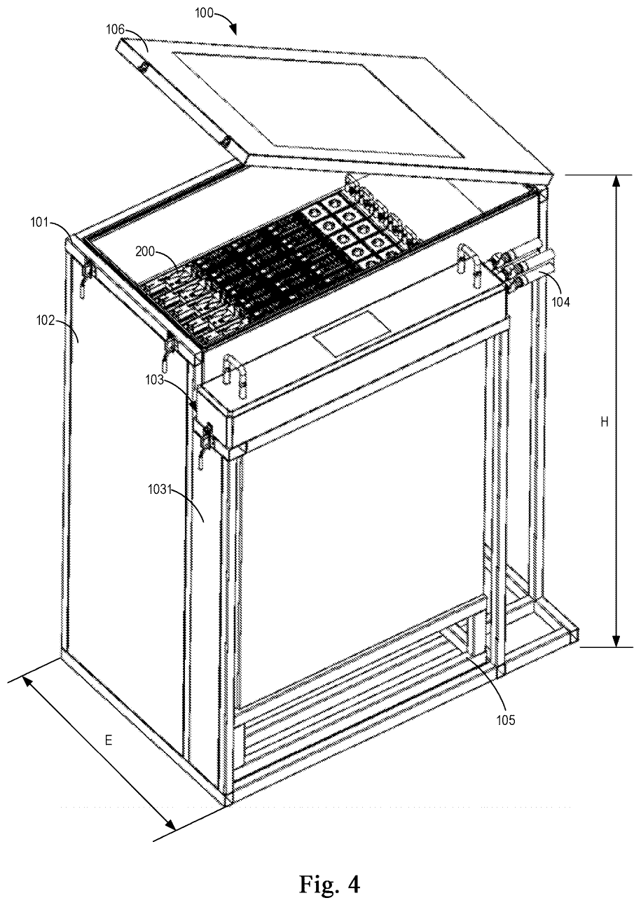

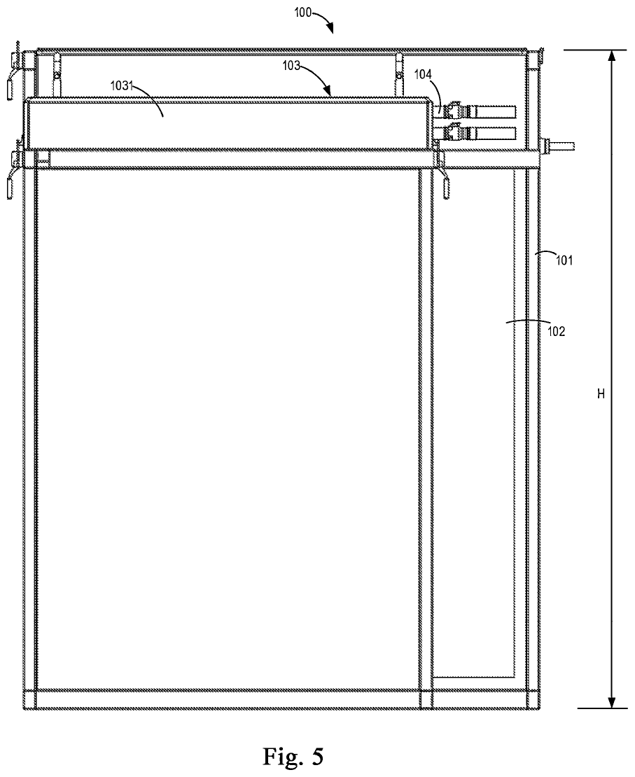

Embodiments of the present disclosure provide an immersion-type liquid-cooling device 100 and an immersion-type liquid-cooling system 300 to at least address or at least partially address the above and other potential problems in conventional immersion-type liquid-cooling device and systems. FIG. 2, FIG. 3 and FIG. 4 show schematic perspective views of the immersion-type liquid-cooling device 100 according to an embodiment of the present disclosure viewed from different angles, and FIG. 5 shows a schematic side view of the immersion-type liquid-cooling device 100, in which a lid 106 of the immersion-type liquid-cooling device 100 in FIG. 4 is opened to display the electronic device(s) therein.

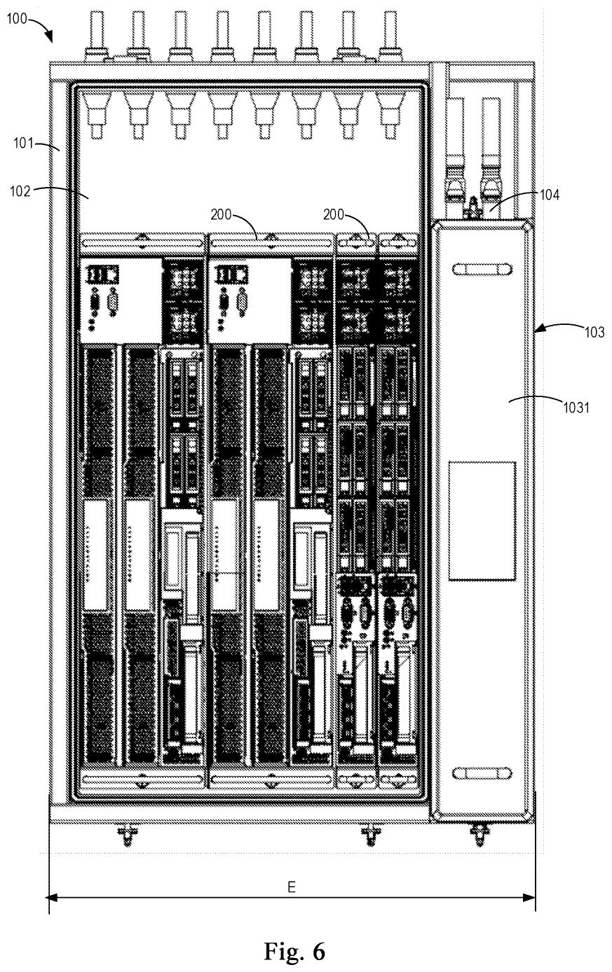

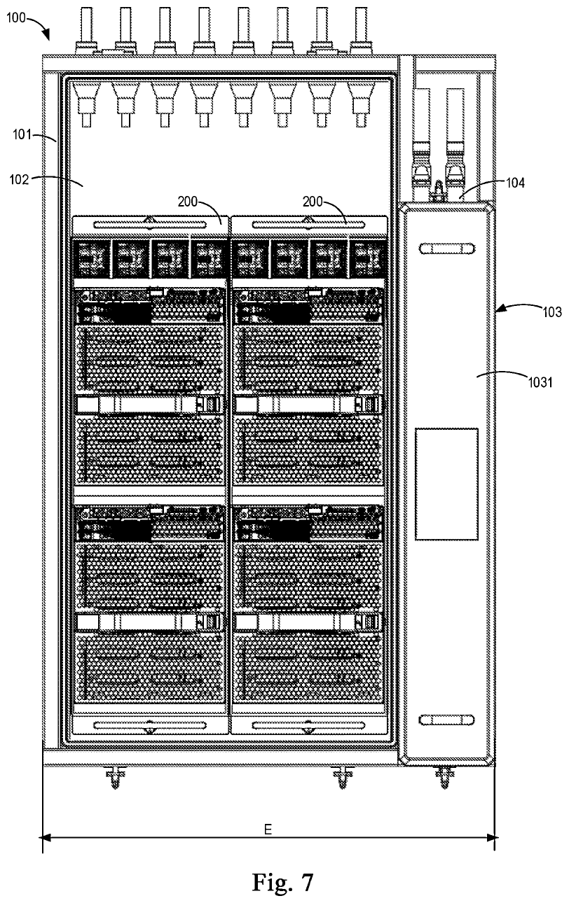

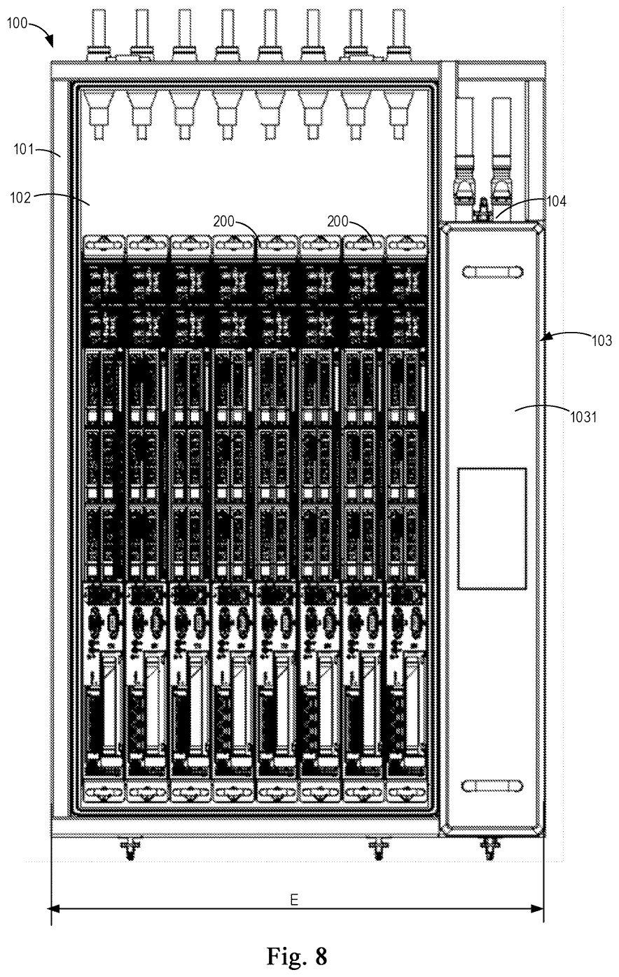

As shown in FIGS. 2-5, the immersion-type liquid-cooling device 100 according to an embodiment of the present disclosure generally includes a cooling tank 102, a main heat dissipation apparatus 103, and a cold source interface 104. The cooling tank 102 is used to accommodate the cooling liquid and the electronic device(s) 200 to be cooled in a sealed manner so as to immerse the electronic device(s) 200 in the cooling liquid. One or more electronic devices 200 may be disposed in the cooling tank 102. A plurality of electronic devices 200 may be arranged in the cooling tank 102 along an extension direction E. The electronic devices 200 in the cooling tank 102 may be various types of servers and may include, for example, but are not limited to, a storage-type server, a computing-type server, a computing-storage integration-type server, and the like, as shown in FIGS. 6-8.

FIGS. 6 to 8 show top views of the cooling tank 102, in which various types of electronic devices 200 accommodated in the cooling tank 102 are respectively shown. As can be seen from FIGS. 6-8, to maximize deployment density, the electronic devices 200 in the cooling tank 102 may be inserted vertically into the cooling tank 102 substantially along the extension direction E. In the cooling tank 102, in order to facilitate the arrangement of the electronic devices 200, a structure or a module for inserting the electronic devices 200 may be provided. In this manner, on the one hand, the electronic devices 200 can be arranged in the cooling tank 102 with a greater density. On the other hand, an operator can more conveniently maintain the electronic devices 200.

For the cooling liquid stored in the cooling tank 102, a non-conductive liquid is used, which may include, but is not limited to, a fluorinated liquid or a mineral oil, for example. Hereinafter, the cooling liquid in the cooling tank 102 will be referred to as a main cooling liquid so as to distinguish it from other cooling liquid(s).

To facilitate maintenance of the electronic device(s) 200 and the main cooling liquid therein, the cooling tank 102 has a top opening. In some embodiments, the entire top area of the cooling tank 102 may be a top opening area to facilitate maintenance of the electronic device(s) 200 and the main cooling liquid. In order to achieve sealing, the liquid cooling device 100 further comprises a lid 106 provided at the top opening of the cooling tank 102. The lid 106 is coupled to the cooling tank 102 in a sealed manner so as to implement the sealing of the cooling liquid. In some embodiments, the lid 106 may be disposed on the cooling tank 102 in a rotatable manner by means of a hinge or the like. When maintenance of the electronic device(s) 200 or the main cooling liquid is required, the lid 106 may be opened by operating the lid 106 to rotate about the hinge. To provide the sealing, a sealing ring may be provided at a location where the lid 106 engages the cooling tank 102.

It should be understood that the embodiment in which the lid 106 is coupled to the cooling tank 102 by the hinge or the like is merely illustrative and is not intended to limit the scope of the present disclosure. Any other suitable manner or arrangement is also possible. For example, in some alternative embodiments, the lid 106 may also be disposed directly on the cooling tank 102 and may be entirely removed from the cooling tank 102.

To facilitate a deployment of the main heat dissipation apparatus 103 and the cooling tank 102, in some embodiments, the immersion-type liquid-cooling device 100 according to embodiments of the present disclosure may further comprise a holder 101. The holder 101 may be a bearing structure which is used to carry the cooling tank 102 and the main heat dissipation apparatus 103. While FIGS. 2-5 show the holder 101 generally having a frame-type configuration, it should be understood that such manner shown in FIGS. 2-5 is merely illustrative and is not intended to limit the scope of protection in accordance with the present disclosure. Any other suitable structure or arrangement is also possible. For example, in some alternative embodiments, the holder 101 may also be constructed of a fully-enclosed or semi-enclosed housing 1031 constructed from plates.

In some embodiments, the cooling tank 102 may be fixedly disposed at a first portion of the holder 101 and the main heat dissipation apparatus 103 may be disposed at a second portion adjacent to the first portion. The cooling tank 102 may be fixedly disposed in the first part, e.g. by welding, fastening, interference fit, etc. The main heat dissipation apparatus 103 may be disposed in the second portion of the holder 101 in a detachable manner to facilitate maintenance and replacement of the main heat dissipation apparatus 103.

In some embodiments, to save space and facilitate arrangement, the first portion for carrying the cooling tank 102 and the second portion for carrying the main heat dissipation apparatus 103 of the holder 101 may have different heights. For example, the height of the portion for carrying the cooling tank 102 of the holder 101 may be greater than the height of the portion for carrying the main heat dissipation apparatus 103, as shown in FIG. 4. It will, of course, be understood that this is merely illustrative and is not intended to limit the scope of the present disclosure. In some alternative embodiments, portions of the holder 101 may also have a uniform height. The use of the holder 101 facilitates modularization of the liquid cooling device 100, thereby making the liquid cooling device 100 easier to be deployed.

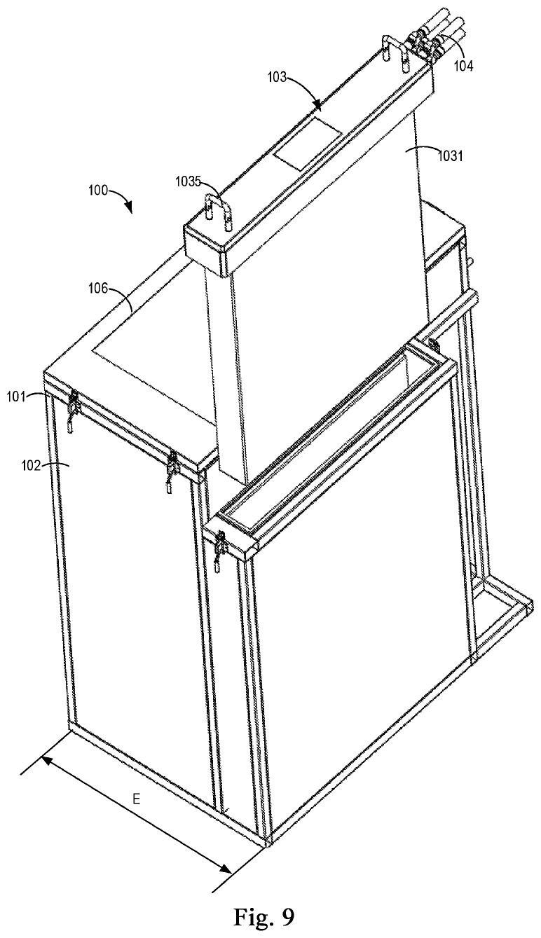

To facilitate the detaching of the main heat dissipation apparatus 103, in some embodiments, the main heat dissipation apparatus 103 may include a handle 1035 disposed at a predetermined location. For example, FIG. 9 shows the handle 1035 being disposed on a top wall of the main heat dissipation apparatus 103. In addition, to facilitate the locking of the main heat dissipation apparatus 103 in the holder 101, in some embodiments, a locking apparatus may further be provided on the holder 101. A locking structure such as a groove, a hole, or a buckle, which cooperates with the locking apparatus, may be provided at a 30) corresponding position of the main heat dissipation apparatus 103. When the main heat dissipation apparatus 103 is placed in place in the holder 101, the locking apparatus may automatically or manually engage the locking structure so as to implement the locking of the main heat dissipation apparatus 103 in the holder 101. When it is necessary to replace or maintain the main heat dissipation apparatus 103, only further operating the handle 1035 after operating the unlocking of locking apparatus is needed to remove the main heat dissipation apparatus 103 from the holder 101 and replace the main heat dissipation apparatus 103 with a new one.

It should be understood that the above embodiments with respect to the main heat dissipation apparatus 103 being indirectly attached to the cooling tank 102 using the holder 101 are illustrative only and are not intended to limit the scope of the present disclosure. The main heat dissipation apparatus 103 and the cooling tank 102 may also be attached in any other suitable manner. For example, in some alternative embodiments, the main heat dissipation apparatus 103 may also be attached directly to the cooling tank 102 in a detachable manner by means such as a clip, a fastener, a groove, or the like. The concept according to the present disclosure will be described below primarily in a manner in which the main heat dissipation apparatus 103 and the cooling tank 102 are coupled to the holder 101 for deployment. It should be understood that other couplings between the main heat dissipation apparatus 103 and the cooling tank 102 are similar and will not be described separately hereinafter.

The main heat dissipation apparatus 103 is a sealed structure including an inner cavity sealed by a housing 1031 and including a main circulating component 1032 and a heat exchanger 1033 accommodated in the inner cavity. In this manner, the main heat dissipation apparatus 103 forms a modular apparatus. The main heat dissipation apparatus 103 is arranged adjacent to the cooling tank 102 when arranged on the holder 101. The inner cavity of the main heat dissipation apparatus 103 is communicated to the cooling tank 102 in a sealed manner. The main circulating component 1032 is used for circulating the main cooling liquid in the cooling tank 102 and the inner cavity, more specifically, outside the cooling tank 102 and the heat exchanger 1033.

The heat exchanger 1033, also called as a thermal transducer, is a device that transfers heat from one medium to another. For this disclosure, the heat exchanger is used to transfer heat of the electronic device(s) 200 from the main cooling liquid to an auxiliary cooling liquid such as deionized water. Heat is conducted through the structure and materials of the heat exchanger 1033 The structure of the heat exchanger 1033 separates the main cooling liquid and the auxiliary cooling liquid. For example, the main cooling liquid flows outside the heat exchanger 1033 and the auxiliary cooling liquid flows inside the heat exchanger. Although that in the exterior of the heat exchanger 1033 will be referred to herein as the main cooling liquid and that in the interior of the heat exchanger 1033 as the auxiliary cooling liquid, it should be understood that this is for the purpose of distinguishing cooling liquids only and is not intended to represent a difference in cooling effect. The heat exchange of the main cooling liquid and the auxiliary cooling liquid at the heat exchanger 1033 in the present disclosure achieves efficient cooling of the electronic device(s) 200. In some cases, the main cooling liquid is also referred to as the primary cooling liquid, and the auxiliary cooling liquid is also referred to as the secondary cooling liquid.

In this manner, the above-described arrangement of the main circulating component 1032 and the heat exchanger 1033 in the main heat dissipation apparatus 103 causes the main heat dissipation apparatus 103 to form a modular apparatus. The main heat dissipation apparatuses 103 with various standards may be provided according to the difference in circulating heat dissipation capability. The user can select the main heat dissipating apparatus 103 with an appropriate standard according to the difference between the electronic devices 200 to be cooled and the difference between the cooling tanks 102 so as to further improve the cooling efficiency, which will be further described later.

In some embodiments, in order to improve the cooling efficiency, the heat exchanger 1033 may have a microstructure such as a labyrinth or the like so that the contact area between the cooling media can be secured to ensure efficient heat exchange. In this way, heat can be dissipated for the electronic device 200 with the greater efficiency.

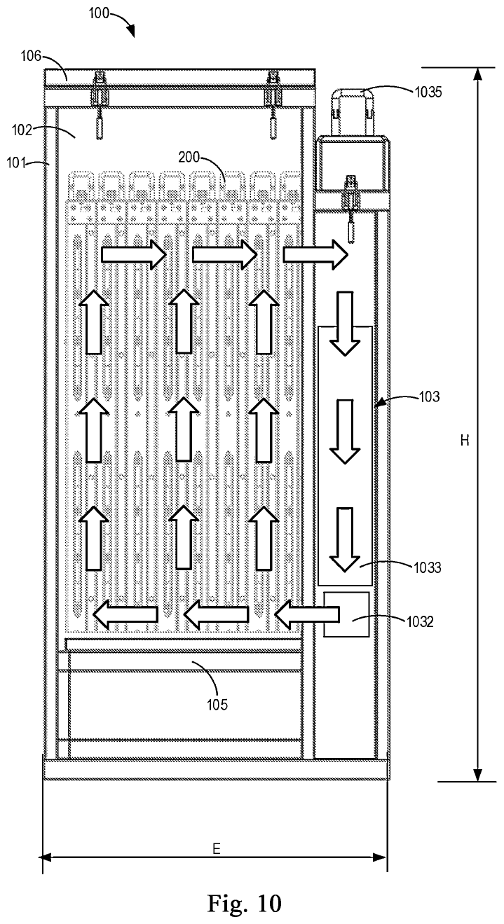

FIG. 10 shows a side cross-sectional view of a liquid cooling device 100 according to an embodiment of the present disclosure. As shown in FIG. 10, in some embodiments, the liquid cooling device 100 further comprises a plurality of inlet and outlet through holes. The inlet and outlet through holes are provided between the cooling tank 102 and the inner cavity of the main heat dissipation apparatus 103. For example, in some embodiments, the inlet and outlet through holes may be provided on a plate or wall disposed between the cooling tank 102 and the interior cavity of the main heat dissipation apparatus 103. The inlet and outlet through holes implement communication of the main cooling liquid between the cooling tank 102 and the inner cavity of the main heat dissipation apparatus 103.

In some embodiments, the inlet and outlet through holes may include a plurality of inlets disposed above and a plurality of outlets disposed below: The terms “in” and “out” refer to the direction of flow of the main cooling liquid relative to the interior cavity of the main heat dissipation apparatus 103. Through the main circulating component 1032, the main cooling liquid will enter the cooling tank 102 from a lower outlet. Driven by the main circulating component 1032, the main cooling liquid entering the cooling tank 102 will flow from bottom to up and eventually re-enter the inner cavity of the main heat dissipation apparatus 103 from an upper inlet. The main cooling liquid is cooled in the inner cavity of the main heat dissipation apparatus 103 by removing heat through the exterior of the heat exchanger 1033 in the main heat dissipation apparatus 103, and re-enters the cooling tank 102 from the lower outlet. The cooling of the electronic device(s) 200 in the cooling tank 102 is implemented in this reciprocating cycle.

On the one hand, this bottom-up circulation of the main cooling liquid in the cooling tank 102 can further facilitate the removal of heat from the electronic device(s) 200. On the other hand, in the inner cavity of the main heat dissipation apparatus 103, the main cooling liquid may pass through the heat exchanger 1033 from top to bottom under the action of gravity and the driving force of the main circulating component 1032, which is more conductive to heat exchange of the main cooling liquid with the auxiliary cooling liquid inside the heat exchanger 1033, and thereby improves the efficiency of heat exchange. In some embodiments, the main circulating component 1032 may include one or more circulating pumps.

In addition, it can also be seen from the foregoing description that the heat exchanger 1033 employed herein is to employ a liquid-liquid heat exchange. This heat exchange mode is more efficient than the gas-liquid heat exchange mode in the conventional scheme, and thus improves the cooling efficiency of the entire liquid cooling device 100.

In some embodiments, a plurality of inlet and outlet through holes may be provided for communicating the cooling tank 102 and the inner cavity in the main heat dissipation apparatus 103. In this way, a redundant design of inlet and outlet through holes is provided. Even if one of the through holes is blocked or the like, the effective flow and circulation of the main cooling liquid communicating between the cooling tank 102 and the inner cavity of the main heat dissipation apparatus 103 is not affected, thereby ensuring the cooling effect.

In addition, it should be noted that the liquid cooling device 100 according to the embodiment of the present disclosure employs a miniaturized device. Specifically, in some embodiments, a size of the immersion-type liquid-cooling device 100 in the extension direction E may be not greater than 1.5 times its height H, or a size of the immersion-type liquid-cooling device 100 may be at most 30U. For example, the size of the immersion-type liquid-cooling device 100 in the extension direction E may be less than the size of its height H. In some alternative embodiments, the size of the immersion-type liquid-cooling device 100 in the extension direction E may be less than one half of the size of its height H. Considering the sizes of most electronic devices 200, the height H of the liquid cooling device 100 is generally about 1 m. That is, in some embodiments, the size of the immersion-type liquid-cooling device 100 in the extension direction E may be not greater than 1.5 meters, e.g. less than 1 meter or 0.5 meters. This allows the liquid cooling device 100 to have a miniaturized size. As mentioned in the foregoing, for the conventional liquid cooling device 100, the length (i.e. the size in the extension direction E) of the single cooling tank 102 is about 2-3 meters, which still does not include the size of the liquid cooling distribution unit or the like required therefor. As mentioned above, the large volume of the cooling tank 102 also brings various problems.

In contrast, for the liquid cooling device 100 according to the present disclosure, the size of the entire liquid cooling device 100 (including the cooling tank 102 and the main heat dissipation apparatus(es) 103) in the extension direction E is not greater than 1.5 meters, for example, 1 meter or less. With the liquid cooling device 100 according to the embodiment of the present disclosure adopting a miniaturized size, on the one hand, an operator can operate and maintain the electronic device(s) 200 therein in all directions of the liquid cooling device 100, making the maintenance more convenient and thus avoiding misoperation, and thereby improving the reliability and efficiency of maintenance.

On the other hand, the miniaturized liquid cooling device 100 employs miniaturized cooling tanks 102, which makes the number of electronic devices 200 stored in each cooling tank 102 small. This enables the operating cost of the electronic devices 200 to be reduced for some businesses that require only a small number of electronic devices 200, but does not affect the application of the immersion-type liquid-cooling device 100 according to embodiments of the present disclosure to a large data center at all. Specifically, although the number of electronic devices 200 stored in the cooling tank 102 according to embodiments of the present disclosure is small, due to the advantages with its modular structure and ease of deployment or the like mentioned above, the needs of the large data center can be meet in a more convenient way by quickly and conveniently deploying multiple liquid cooling modules.

In addition, the use of the miniaturized liquid cooling devices 100 is advantageous in that, due to the small number of electronic devices 200 stored in the cooling tank 102, if one of the liquid cooling devices 100 malfunctions, the induced influence and loss are greatly reduced compared to the conventional large cooling tank 102, thereby further reducing the malfunction cost and maintenance cost.

Further, the combination of the miniaturized cooling tank(s) 102 and the main heat dissipation apparatus(es) 103 also makes the control of the liquid level of the main cooling liquid in the cooling tank 102 more accurate. For the conventional large cooling tank 102, the control accuracy for the liquid level of its cooling liquid can be on the order of centimeters at most. For the liquid cooling device 100 according to the embodiment of the present disclosure, the control accuracy for the liquid level of the main cooling liquid can be on the order of millimeters. The improved control accuracy for the liquid level of the main cooling liquid also results in more optimal control of the heat dissipation and cost of the electronic device(s) 200.

In some embodiments, the cooling tanks 102 may be set with various standards to accommodate multiple types of electronic devices 200 with different sizes. The depths of the cooling tanks 102 may vary for a variety of standards. For some electronic devices 200 with smaller sizes, cooling tanks 102 having smaller depth standards may be used. For some electronic devices 200 with larger sizes, cooling tanks 102 having larger depth standards may be used. This arrangement can further reduce the waste of the main cooling liquid, thereby improving the utilization rate of the main cooling liquid.

In order to facilitate the deployment of cooling tanks 102 with different depths, in some embodiments, the liquid cooling device 100 may further include a lifting bracket 105 applied for cooling tank(s) 102 with smaller standard(s). By using the lifting bracket 105, a shortfall in the height of the liquid cooling device(s) 100 having cooling tank(s) 102 with smaller standard(s) can be compensated, thereby causing it (or them) to be consistent with the liquid cooling device(s) 100 having cooling tank(s) 102 with higher standard(s). For example, the cold source interfaces 104 can be maintained at the same level so as to further facilitate the large-scale deployment of the liquid cooling devices 100.

In some embodiments, alternatively or additionally, the sizes of the cooling tanks 102 in the extension direction E may be different for various standards. In this way, cooling tanks 102 with various standards can be used to accommodate different numbers of electronic devices or different types of electronic devices 200 so that the cooling tank(s) 102 with an appropriate size (or appropriate sizes) can be selected based on the type and number of electronic devices to be cooled, thereby avoiding the waste of main cooling liquid and further reducing the cost.

Similar to the cooling tanks 102, in some embodiments, the main heat dissipation apparatus 103 may also be set with a variety of different standards due to a modular design of the main heat dissipation apparatuses 103, thereby facilitating application to cooling tanks 102 and/or electronic devices 200 with different standards. Main heat dissipation apparatuses 103 with different standards can have different capabilities for circulating heat dissipation of the cooling liquid and can be sized to match different sizes of cooling tanks 102 with different standards. First, the circulation capacities of the main heat dissipation apparatuses 103 may be different for different standards. The circulation capacity indicates the amount of cooling liquid that can be treated per unit time. The higher the circulation capacity, the more the amount of cooling liquid treated per unit time, and the lower the circulation capacity; the less the amount of cooling liquid treated per unit time. For example, for some cooling tanks 102 having smaller depth standards, it may be possible to cooperate with the main heat dissipation apparatuses 103 having less circulation capacities due to the relatively less main cooling liquid used therein. Similarly, for some cooling tanks 102 having larger depth standards, it may be possible to cooperate with the main heat dissipation apparatuses 103 having larger circulation capacities due to the relatively large amount of main cooling liquid used therein. This arrangement further facilitates providing more precise control of heat dissipation from the electronic devices 200 in a more cost-effective manner.

Secondly, alternatively or additionally, the heat dissipation capacities of the main heat dissipation apparatuses 103 with different standards may be different. The heat dissipation capacity may be manifested by the difference in the volume and/or microstructure of the heat exchanger. For example, the larger the volume of the heat exchanger and/or the more optimized the microstructure in the heat exchanger, the better the heat dissipation capacity, the smaller the volume of the heat exchanger and/or the larger the microstructure in the heat exchanger, the worse the heat dissipation capacity. In this way, a main heat dissipation apparatus 103 having an appropriate heat dissipation capability can be selected based on factors such as the number of electronic devices 200 to be cooled, thereby providing more precise control of the heat dissipation of the electronic devices 200 in a more cost-effective manner.

Further, as mentioned in the foregoing, since the main heat dissipation apparatus 103 is detachably arranged on the holder 101, when a failure occurs or the main heat dissipation apparatus 103 used has an insufficient circulation capacity, the original main heat dissipation apparatus 103 can be removed from the holder 101 and a new main heat dissipation apparatus 103 can be assembled at a predetermined position of the holder 101 as shown in FIG. 9. The inlet and outlet through holes between the inner cavity of the main heat dissipation apparatus 103 and the cooling tank 102 are then sealed with a sealing ring to prevent leakage of the main cooling liquid. Once the sealing ring is assembled, the main circulating component 1032 having a suitable circulation capability may be used to circulate the main cooling liquid between the inner cavity of the main heat dissipation apparatus 103 and the cooling tank 102. In this way, on the one hand, the modular detachable arrangement of the main heat dissipation apparatus 103 further facilitates maintenance of the main heat dissipation apparatus 103 or even the entire immersion-type liquid-cooling device 100. On the other hand, this makes it possible to flexibly adjust the main heat dissipation apparatus 103 according to the conditions of the cooling tanks 102 and the electronic devices 200, so that the cooling effect can be ensured with high cooling efficiency.

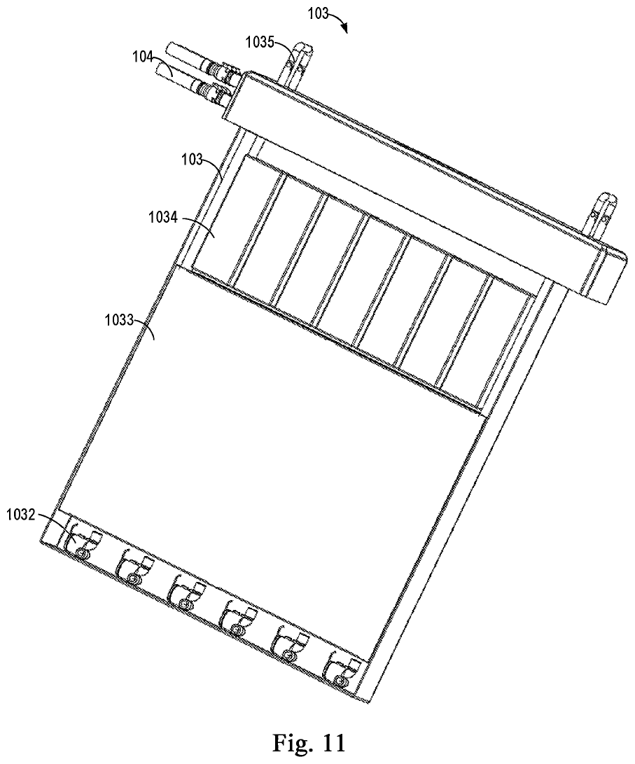

In some embodiments, considering the space occupied by the main circulating component 1032 and the heat exchanger 1033 in the main heat dissipation apparatus 103, in order to further reduce the amount of main cooling liquid used, a liquid occupied block 1034 may further be provided in the main heat dissipation apparatus 103, as shown in FIG. 11. The liquid occupied block 1034 is a suitable object for occupying the empty volume in the inner cavity of the main heat dissipation apparatus 103. In some embodiments, the liquid occupied block 1034 is also disposed above the heat exchanger 1033. With the use of the liquid occupied block 1034, the amount of main cooling liquid used can be further reduced, thereby further reducing the cost.

The liquid occupied block 1034, on the one hand, can occupy the volume in the inner cavity of the main heat dissipation apparatus 103 so as to reduce the consumption of main cooling liquid and, on the other hand, allows the main cooling liquid to flow therethrough or thereabouts without impeding the circulation of the main cooling liquid. The liquid occupied block 1034 may take a variety of different configurations or forms. For example, in some embodiments, the liquid occupied block 1034 may comprise a plurality of individual pieces. The plurality of individual pieces is arranged in the empty space of the inner cavity of the main heat dissipation apparatus 103 in a stacked or side-by-side arrangement or the like, a gap may be provided therebetween to facilitate the flow of the main cooling liquid so as to avoid the obstruction of flow of the main cooling liquid by the liquid occupied block 1034. Alternatively or additionally, in some embodiments, the liquid occupied block 1034 may also employ a porous configuration to facilitate the flow of the main cooling liquid.

Of course, it should be understood that the embodiments described above with respect to the main heat dissipation apparatus 103 in connection with FIGS. 9-11 are merely illustrative and are not intended to limit the scope of the present disclosure. The main heat dissipation apparatus 103 may have any other suitable structure or configuration. For example, in some embodiments, the liquid occupied block 1034 may also be disposed below the heat exchanger 1033 or at any other suitable location.

In some embodiments, a control apparatus may further be provided on the main heat dissipation apparatus 103 to view at least the state (e.g. liquid level, temperature, etc.) of the main cooling liquid in the liquid cooling device 100 and/or to control the main circulating component 1033. In some embodiments, the control apparatus may further include a display unit. The display unit may have a touch control unit to facilitate control of the main circulating component 1033. Of course, in some alternative embodiments, the control apparatus may further include a button or the like to facilitate control of the main circulating component 1033.

With the adoption of the control apparatus, it is possible to control parameters such as the power of the main circulating component 1033 according to information such as the amount of heat generated by the electronic device(s) 200 to be cooled in the cooling tank 102 and the number of the electronic device(s) 200 to be cooled in the cooling tank 102, thereby reducing the cooling cost while improving the cooling efficiency. For example, in a case that the number of electronic devices 200 stored in the cooling tanks 102 is reduced, the operating cost can be further reduced by the control apparatus lowering the power of the main circulating component 1033. Of course, in some alternative embodiments, the control apparatus may further display other information and/or control other components. For example, in some embodiments, the display unit of the control apparatus may further display the type and number of electronic devices 200 to be cooled in the immersion-type liquid-cooling device 100, etc.

To facilitate the deployment, the liquid cooling device 100 includes a cold source interface 104 coupled to the main heat dissipation apparatus 103. For example, in some embodiments, the cold source interface 104 may be at least partially disposed on the housing 1031 of the main heat dissipation apparatus 103. The cold source interface 104 is adapted for the communication of the auxiliary cooling liquid between the external cold source 302 and the interior of the heat exchanger 1033 to thereby cause the auxiliary cooling liquid in the external cold source 302 and the main cooling liquid to exchange heat at the heat exchanger 1033. In some embodiments, the auxiliary cooling liquid may include deionized water. The use of deionized water can effectively avoid the corrosion and influence on the structure inside the heat exchanger 1033 and the metal of cooling pipelines, thereby improving the reliability of the liquid cooling system.

In some embodiments, the cold source interface 104 may also be provided with at least two sets. In this way, a redundant design of the cold source interfaces 104 is provided. And the processing capacity of each set of cold source interfaces 104 for the auxiliary cooling liquid can completely satisfy the circulation requirements of the auxiliary cooling liquid. In this case, even if one of the sets of cold source interfaces 104 is clogged or the like, the circulation of the auxiliary cooling liquid is not affected at all, thereby ensuring the cooling effect.

By integrating the main heat dissipation apparatus 103 with both internal and external circulation capabilities and the cooling tank 102, a modular liquid cooling device is formed. When deploying the liquid cooling device 100 according to an embodiment of the present disclosure, the deployment can be accomplished by only coupling the reserved interface of the data center and the cold source interface 104 of the liquid cooling device, thereby forming a distributed liquid cooling system 300. In this way, the deployment of the liquid cooling device is significantly simplified.

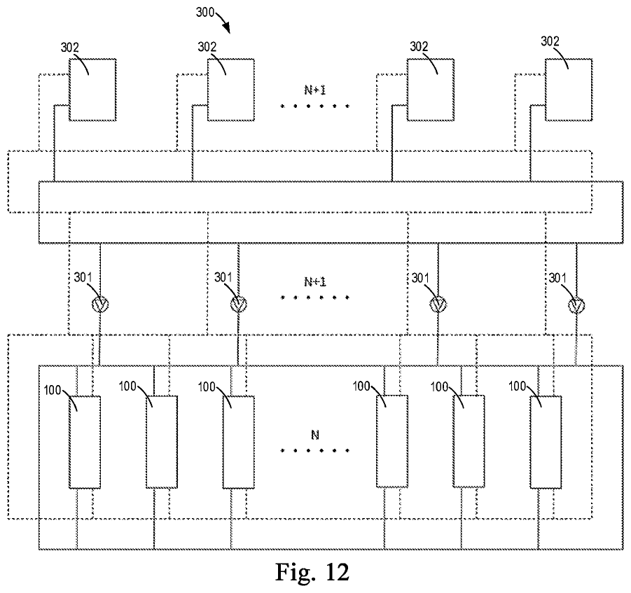

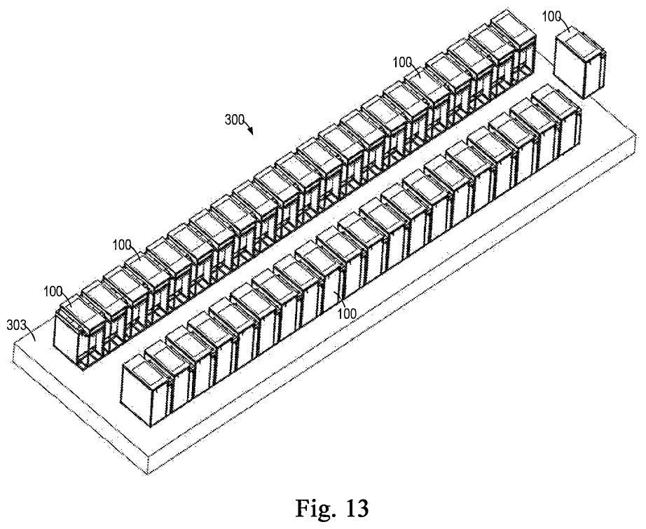

FIG. 12 shows a system architecture diagram of a liquid cooling system 300 employing an immersion-type liquid-cooling device 100 according to an embodiment of the present disclosure, and FIG. 13 shows a diagram in which a plurality of liquid cooling devices 100 are arranged in an array in the immersion-type liquid-cooling system 300 according to an embodiment of the present disclosure.

In general, the immersion-type liquid-cooling system 300 according to an embodiment of the present disclosure includes at least one liquid cooling device 100 as previously described and an auxiliary cooling apparatus 301. While FIGS. 12 and 13 illustrate the presence of a plurality of liquid cooling devices 100 in the immersion-type liquid-cooling system 300, it should be understood that this is merely illustrative and is not intended to limit the scope of the present disclosure. The number of liquid cooling devices 100 may be one or more according to the needs of different data centers.

As mentioned in the foregoing, in some embodiments, to facilitate the deployment of the liquid cooling device(s) 100, the immersion-type liquid-cooling system 300 may include a plurality of reserved interfaces. The reserved interface is in communication with an external cold source 302 through an auxiliary cooling apparatus and may be used to couple to the plurality of cold source interfaces 104 of the liquid cooling device 100 according to embodiments of the present disclosure. In this way, the heat exchanger 1033 in the liquid cooling device 100 can communicate with the external cold source 302 through the auxiliary cooling apparatus 301. The external cold source 302 may be a cooling tower in some embodiments.

In this manner, it is possible to effectively reduce the investment in the data center and the overall operation cost, so that the overall power efficiency index of the data center can be controlled at 1.1 or even lower. For example, in designing a liquid cooling system for a data center, a predetermined number of reserved interfaces and liquid cooling devices 100 may be provided in designing the liquid cooling system 300 to meet the needs of a large number of servers in a future data center, taking into account the future large scale of data center. With respect to the number of electronic devices 200, a smaller number of electronic devices 200 may be placed into a portion of the liquid cooling device 100, taking into account the relatively small number of servers initially required by the data center. For the liquid cooling device 100 in which no electronic device 200 is placed, the main cooling liquid may be temporarily not provided and not circulated. With the continuous development of business, when the scale of the data center needs to be expanded later, it is only necessary to increase the required server(s) and arrange the server(s) in the liquid cooling device(s) 100 provided with the main cooling liquid(s), without redesigning and manufacturing the entire liquid cooling system, thereby effectively reducing the initial investment of the data center and the overall operation cost, and also making the adjustment of the data center simpler and more flexible.

Of course, in some alternative embodiments, it is also possible to deploy only a quantity of liquid cooling apparatuses 100 corresponding to the number of servers, with the cold source interfaces 104 of the liquid cooling apparatuses 100 being coupled to a part of the reserved interfaces for effective cooling of the servers. As the business volume increases, when it is necessary to add server(s), it is only necessary to add the server(s) and correspondingly increase the number of the liquid cooling devices 100 according to the number of the added server(s), and to couple the cold source interfaces 104 of the liquid cooling devices 100 with the remaining reserved interfaces until the deployment of the entire liquid cooling system is finally completed.

Further, in deploying the immersion-type liquid-cooling device 100 of embodiments of the present disclosure, no additional cold distribution unit is required, but only the cold source is required to be connected with the present liquid cooling device 100 through the cold source interface 104, which significantly simplifies the design and deployment difficulty of the immersion-type liquid-cooling system 300, thereby effectively improving the efficiency and reducing the cost.

In some embodiments, to further simplify the deployment, the immersion-type liquid-cooling system 300 may further include a base 303. A predetermined position on the base 303 may be provided with a groove or receptacle for providing the liquid cooling device 100, and a corresponding reserved interface. In this way, when it is desired to deploy the liquid cooling device 100, it is only necessary to dispose the liquid cooling device 100 in the receptacle of the base 303 and connect its cold source interface 104 with the corresponding reserved interface, thereby further simplifying the deployment of the immersion-type liquid-cooling system 300.

For example, in a large-scale cluster deployment of the electronic devices 200, the base 303 may be provided in the data center in advance, and the external cold source 302, the auxiliary cooling apparatus 301, and the reserved interface may be debugged. A smaller number of electronic devices 200 may be used in the early stages of data center construction to meet the earlier demand for smaller business volume. With the continuous development of businesses, electronic devices 200 may be repurchased and deployed into the liquid-cooled system 300 to thereby complete the deployment of the entire system. With the used of the base 303, the deployment time for the data center can be further reduced and the deployment efficiency is improved.

It should be understood that the above detailed embodiments of the disclosure are merely illustrative or explanatory of the principles of the disclosure and are not intend to limit the disclosure. Accordingly, it is intended to encompass all such alternatives, modifications and variations that fall within the spirit and broad scope of the present disclosure. Also, the claims appended to this disclosure are intended to cover all such changes and modifications that fall within the scope and range or equivalents of the claims.

I/We claim:

1. An immersion-type liquid-cooling device comprising:
a cooling tank adapted to accommodate a main cooling liquid in a sealed manner so as to immerse, in the main cooling liquid, an electronic device to be cooled;
a main heat dissipation apparatus attached to the cooling tank and comprising an inner cavity enclosed by a housing and a main circulating component and a heat exchanger accommodated in the inner cavity, wherein the inner cavity is in communication with the cooling tank in a sealed manner, and the main circulating component is adapted to circulate the main cooling liquid between the cooling tank and an exterior of the heat exchanger; and
a cold source interface coupled to the main heat dissipation apparatus and configured to allow an auxiliary cooling liquid to circulate between an external cold source and an interior of the heat exchanger such that the auxiliary cooling liquid exchanges heat with the main cooling liquid at the heat exchanger.

2. The immersion-type liquid-cooling device of claim 1, wherein the main heat dissipation apparatus is detachably attached to the cooling tank.

3. The immersion-type liquid-cooling device of claim 1, further comprising:
a holder adapted to carry the cooling tank and the main heat dissipation apparatus.

4. The immersion-type liquid-cooling device of claim 1, wherein the one or more electronic devices are arranged in the cooling tank along an extension direction, and
a size of the immersion-type liquid-cooling device in the extension direction is not greater than 1.5 times a size of a height of the immersion-type liquid-cooling device.

5. The immersion-type liquid-cooling device of claim 4, wherein the size of the immersion-type liquid-cooling device in the extension direction is less than the size of the height of the immersion-type liquid-cooling device.

6. The immersion-type liquid-cooling device of claim 4, wherein the size of the immersion-type liquid-cooling device in the extension direction is less than a size of one half of the height of the immersion-type liquid-cooling device.

7. The immersion-type liquid-cooling device of claim 1, further comprising:
a plurality of inlet and outlet through holes arranged between the cooling tank and the inner cavity of the main heat dissipation apparatus for circulating the main cooling liquid between the cooling tank and the exterior of the heat exchanger.

8. The immersion-type liquid-cooling device of claim 7, wherein the cooling tank is set with a plurality of standards, and cooling tanks with the plurality of standards differ in depth and/or in size in the extension direction, and
the holder is adapted to accommodate a cooling tank with at least one of the plurality of standards.

9. The immersion-type liquid-cooling device of claim 8, further comprising a lifting bracket coupled to the holder and adapted to support at least one of the cooling tank and the main heat dissipation apparatus.

10. The immersion-type liquid-cooling device of claim 1, wherein the main heat dissipation apparatus is set with a plurality of standards, and main heat dissipation apparatuses with the plurality of standards have different circulating heat dissipation capacities, and
the holder is adapted to accommodate the main heat dissipation apparatus with at least one of the plurality of standards.

11. The immersion-type liquid-cooling device of claim 1, further comprising a lid coupled to the cooling tank to seal a top opening of the cooling tank.

12. The immersion-type liquid-cooling device of claim 11, wherein the lid is coupled to the cooling tank by a hinge in a rotatable manner.

13. The immersion-type liquid-cooling device of claim 1, wherein the main heat dissipation apparatus further comprises a liquid occupied block arranged in the inner cavity.

14. The immersion-type liquid-cooling device of claim 1, wherein the cold source interface comprises at least two sets of cold source interfaces.

15. The immersion-type liquid-cooling device of claim 1, wherein the cold source interface is at least partially arranged on the housing.

16. An immersion-type liquid-cooling system comprising:
at least one immersion-type liquid-cooling device comprising:
a cooling tank adapted to accommodate a main cooling liquid in a sealed manner so as to immerse, in the main cooling liquid, an electronic device to be cooled:
a main heat dissipation apparatus attached to the cooling tank and comprising an inner cavity enclosed by a housing and a main circulating component and a heat exchanger accommodated in the inner cavity, wherein the inner cavity is in communication with the cooling tank in a sealed manner, and the main circulating component is adapted to circulate the main cooling liquid between the cooling tank and an exterior of the heat exchanger; and
a cold source interface coupled to the main heat dissipation apparatus and configured to allow an auxiliary cooling liquid to circulate between an external cold source and an interior of the heat exchanger such that the auxiliary cooling liquid exchanges heat with the main cooling liquid at the heat exchanger; and
an auxiliary cooling apparatus coupled to the cold source interface of the at least one immersion-type liquid-cooling device and adapted to circulate the auxiliary cooling liquid between the external cold source and the interior of the heat exchanger.

17. The immersion-type liquid-cooling system of claim 16, wherein the at least one immersion-type liquid-cooling device comprises a plurality of immersion-type liquid-cooling devices, and
the immersion-type liquid-cooling system further comprises a plurality of reserved interfaces adapted to be coupled to the cold source interface.

18. The immersion-type liquid-cooling system of claim 17, further comprising:
a base comprising a plurality of accommodating portions provided at predetermined positions for providing the plurality of immersion-type liquid-cooling devices, the plurality of accommodating portions corresponding to the plurality of reserved interfaces.

19. The immersion-type liquid-cooling system of claim 16, wherein the main cooling liquid comprises a fluorinated liquid or a mineral oil; and/or
the auxiliary cooling liquid comprises deionized water.

20. An immersion-type liquid-cooling system for a large-scale cluster deployment comprising:
a base comprising a plurality of accommodating portions provided at predetermined positions:
a plurality of reserved interfaces corresponding to positions of the plurality of accommodating portions:
an auxiliary cooling apparatus configured between the plurality of reserved interfaces and an external cold source; and
a plurality of immersion-type liquid-cooling devices arranged in the accommodating portions, one of the plurality of immersion-type liquid-cooling devices comprising:
a cooling tank adapted to accommodate a main cooling liquid in a sealed manner so as to immerse, in the main cooling liquid, an electronic device to be cooled:
a main heat dissipation apparatus attached to the cooling tank and comprising an inner cavity enclosed by a housing and a main circulating component and a heat exchanger accommodated in the inner cavity, wherein the inner cavity is in communication with the cooling tank in a sealed manner, and the main circulating component is adapted to circulate the main cooling liquid between the cooling tank and an exterior of the heat exchanger; and
a cold source interface coupled to the main heat dissipation apparatus and configured to allow an auxiliary cooling liquid to circulate between an external cold source and an interior of the heat exchanger such that the auxiliary cooling liquid exchanges heat with the main cooling liquid at the heat exchanger,
wherein cold source interfaces of the immersion-type liquid-cooling devices are coupled to the plurality of reserved interfaces.
